(19) United States
(12) Patent Application Publication
(10) Pub. No.: US 2015/0097217 A1
(43) Pub. Date: Apr. 9, 2015

(54) SEMICONDUCTOR ATTENUATED FINS

(71) Applicant: INTERNATIONAL BUSINESS MACHINES CORPORATION, Armonk, NY (US)

(72) Inventors: Kangguo Cheng, Schenectady, NY (US); Ali Khakifirooz, Mountain View, CA (US); Jinghong Li, Poughquag, NY (US); Alexander Reznicek, Troy, NY (US)

(73) Assignee: INTERNATIONAL BUSINESS MACHINES CORPORATION, Armonk, NY (US)

(21) Appl. No.: 14/045,176

(22) Filed: Oct. 3, 2013

(51) Int. Cl. H01L 29/78; H01L 29/66

(52) U.S. Cl. CPC H01L 29/785; H01L 29/66795
USPC 257/288; 438/479

(57) ABSTRACT

A semiconductor device includes a semiconductor substrate and attenuated semiconductor fins (e.g. FinFET fins) that include an outer portion that is a composite of a first material and a second material, an inner portion that is the second material, and an attenuation portion that is an attenuated composite of the first and second materials. The attenuation portion may be formed by diffusing the first material into a plurality of fins made of the second material. The attenuated composite attenuates from a first composite to a second composite, the first composite comprising a majority of the first material, the second composite comprising a majority of the second material. The outer portion may be located on the fin perimeter and the inner portion may be located central to the fin. The first material may be Germanium, the second material may be Silicon, and the attenuated composite may be attenuated Silicon Germanium.

### FIELD OF THE INVENTION

Embodiments of invention generally relate to semiconductors and the fabrication of semiconductor device components, such as FinFETs, and more particularly to the formation and structure of attenuated fins.

### DESCRIPTION OF THE RELATED ART

While multi-gate, tri-gate architectures, etc., generically known as FinFET technology, deliver superior levels of scalability, semiconductor engineers face challenges in creating devices that optimize the promise of FinFETs.

Design metrics including power, performance, cost, area, and time to market have posed challenges since the inception of the semiconductor integrated circuit industry. However, as process technologies continue to shrink, it becomes increasingly challenging to achieve a similar scaling of certain device parameters, particularly the supply voltage. Additionally, optimizing for one variable such as performance typically results in unwanted compromises in other areas, like power. However, utilizing FinFETs, as compared to planar technology, results in much better performance at the same power budget, or equal performance at a much lower power budget. A particular challenge, as feature size has become smaller, is high leakage current due to short-channel effects and varying dopant levels. Though typical FinFETs generally improve short-channel effects significant challenges exist.

### SUMMARY OF THE INVENTION

Embodiments of invention generally relate to semiconductors and the fabrication of semiconductor device components, such as FinFETs, and more particularly to the formation and structure of attenuated fins.

In a first embodiment, a method of fabricating a semiconductor device includes providing a semiconductor substrate and forming attenuated fins upon the substrate. The attenuated fins include an outer portion that is a composite of a first material and a second material, an inner portion that is a second material, and an attenuation portion that is an attenuated composite of the first material and the second material. In certain embodiments, forming attenuated fins upon the substrate further includes depositing the first material onto the substrate surrounding a plurality of fins that are made of the second material and diffusing the first material into the plurality of fins. In certain embodiments, the first material is Germanium (Ge), the second material is Silicon (Si), and the attenuated composite is attenuated SiGe.

In another embodiment, a semiconductor device includes the silicon substrate and the plurality of attenuated fins upon the substrate. In certain embodiments, the attenuated composite attenuates, varies, gradually varies, or otherwise changes from a first composite to a second composite. The first composite includes a majority of the first material and the second composite includes a majority of the second material. The first composite is generally nearest the outer portion and the second composite being nearest the inner portion. In certain embodiments, the outer portion is located on the fin perimeter and the inner portion is located central to the fin.

In another embodiment, a design structure embodied in a machine readable storage medium for designing, manufacturing, or testing an integrated circuit includes the silicon substrate and the plurality of attenuated fins upon the substrate.

These and other features, aspects, and advantages will become better understood with reference to the following description, appended claims, and accompanying drawings.

### BRIEF DESCRIPTION OF THE DRAWINGS

So that the manner in which the above recited features of the embodiments are attained and can be understood in detail, a more particular description of the embodiments, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 and FIG. 2 depict cross section views of a semiconductor structure shown at intermediate steps during a process flow, in accordance with various embodiments of the present invention.

FIG. 3 depicts a detailed cross section view of a semiconductor structure shown at an intermediate step during a process flow, in accordance with various embodiments of the present invention.

FIG. 4 depicts a partial cross section view of an attenuated fin, in accordance with various embodiments of the present invention.

FIG. 5, FIG. 6, FIG. 7, and FIG. 8 depict cross section views of a semiconductor structure shown at intermediate steps during a process flow, in accordance with various embodiments of the present invention.

FIG. 9 depicts a detailed cross section view of a semiconductor structure shown at an intermediate step during a process flow, in accordance with various embodiments of the present invention.

FIG. 10 depicts a partial cross section view of a multi dimensional attenuated fin, in accordance with various embodiments of the present invention.

FIG. 11 depicts a cross section view of a semiconductor structure shown at intermediate steps during a process flow, in accordance with various embodiments of the present invention.

FIG. 12 depicts a detailed cross section view of a semiconductor structure shown at an intermediate step during a process flow, in accordance with various embodiments of the present invention.

FIG. 13 depicts a cross section view of a semiconductor structure shown at intermediate steps during a process flow, in accordance with various embodiments of the present invention.

FIG. 14 depicts a process of fabricating a semiconductor device, in accordance with various embodiments of the present invention.

FIG. 15 depicts a process of forming attenuated fins, in accordance with various embodiments of the present invention.

FIG. 16 depicts a flow diagram of a design process used in semiconductor design, manufacture, and/or test, in accordance with various embodiments of the present invention.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION OF THE PREFERRED EMBODIMENTS

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments of invention generally relate to the fabrication of FinFET devices, and more particularly to the formation and structure of attenuated fins. A FinFET device may include a plurality of fins formed in a wafer and a gate covering a portion of the fins. A portion of the fins may be covered by the gate and serves as a channel region of the device. A portion of the fins may extend out from under the gate and may serve as source and drain regions of the device. Typical integrated circuits may be divided into active areas and non-active areas. The active areas may include FinFET devices. Each active area may have a different pattern density, or a different number of FinFET devices.

Specific embodiments described herein relate to SiGe Fins. SiGe fins may be preferable in certain implementation since requisite threshold voltages in systems with SiGe fins may be lower relative to systems with Si Fins. Lower threshold voltages lead to, for example, lower turn on voltage, lower energy consumption. etc. SiGe fins may further be preferable since mobility is higher in systems that utilize SiGe Fins relative to systems that utilize Si Fins.

Referring now to FIGS., exemplary process steps of forming a structure 100 in accordance with embodiments of the present invention are shown, and will now be described in greater detail below. It should be noted that some of the FIGS. depict a cross section view of structure 100 having a plurality of fins formed in a semiconductor substrate or bulk. Furthermore, it should be noted that while this description may refer to some components of the structure 100 in the singular tense, more than one component may be depicted throughout the figures and like components are labeled with like numerals. The particular cross section view orientation and specific number of fins depicted in the figures were chosen for illustrative purposes only.

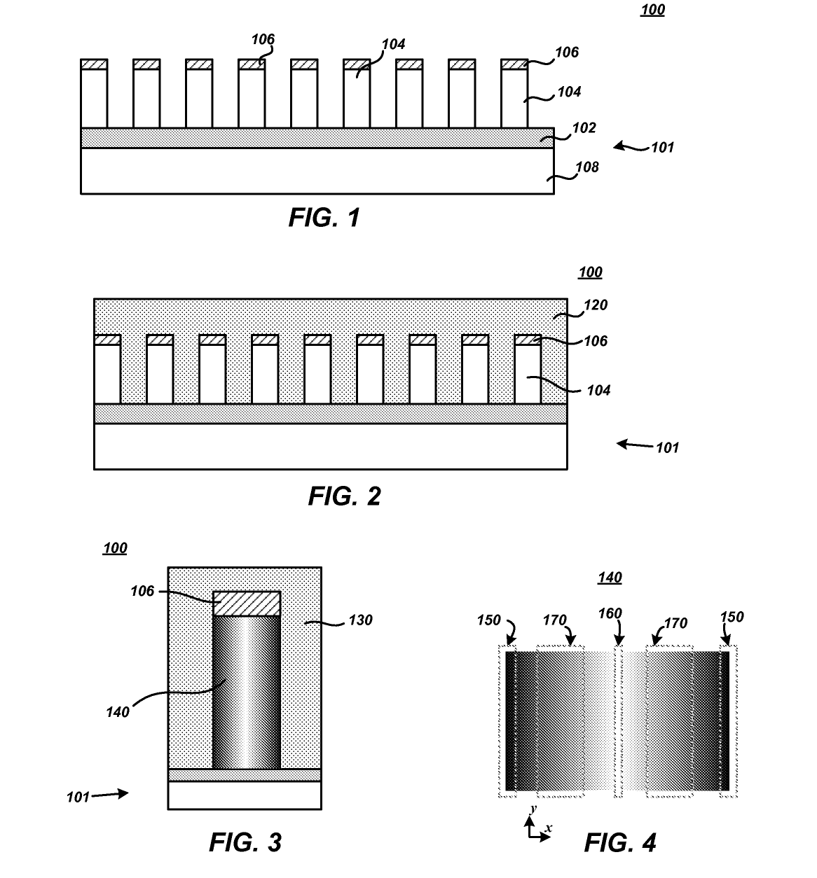

Referring now to FIG. 1, a cross section view of structure 100 is shown at an intermediate step during a process flow. At this step of fabrication, structure 100 may generally include a plurality of fins 104 etched upon substrate 101 that has a cap layer 106 thereon.

The semiconductor substrate 101 may include a bulk semiconductor or a layered semiconductor such as Si/SiGe, a silicon-on-insulator (SOI), or a SiGe-on-insulator (SGOI). Bulk semiconductor substrate materials may include undoped Si, n-doped Si, p-doped Si, single crystal Si, polycrystalline Si, amorphous Si, Ge, SiGe, SiC, SiGeC, GaAs, InP and all other III/V or II/VI compound semiconductors. In the embodiment shown in FIG. 1 a SOI substrate is depicted, however for the purposes of clarity, the various embodiments of the present invention may be applied utilizing a bulk substrate. The SOI substrate may include a base substrate 108, a buried dielectric layer 102 formed on top of the base substrate 108, and a SOI layer (not shown) formed on top of the buried dielectric layer 102. The buried dielectric layer 102 may isolate the SOI layer from the base substrate 108. The plurality of fins 104 may be etched from the SOI layer.

The base substrate 108 may be any of several known semiconductor materials such as, for example, silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. Typically the base substrate 108 may be about, but is not limited to, several hundred microns thick. For example, the base substrate 108 may have a thickness ranging from 0.5 mm to about 1.5 mm.

The buried dielectric layer 102 may include any of several dielectric materials, for example, oxides, nitrides and oxynitrides of silicon. The buried dielectric layer 102 may also include oxides, nitrides and oxynitrides of elements other than silicon. In addition, the buried dielectric layer 102 may include crystalline or non-crystalline dielectric material. Moreover, the buried dielectric layer 102 may be formed using any of several known methods, for example, thermal or plasma oxidation or nitridation methods, chemical vapor deposition methods, and physical vapor deposition methods. The buried dielectric layer 102 may have a thickness ranging from about 5 nm to about 200 nm.

The SOI layer may include any of the several semiconductor materials included in the base substrate 108. In general, the base substrate 108 and the SOI layer may include either identical or different semiconducting materials with respect to chemical composition, dopant concentration and crystallographic orientation. In particular embodiments described herein, the base substrate 108 and the SOI layer include semiconducting materials that include at least different crystallographic orientations. The SOI layer may include a thickness ranging from about 5 nm to about 100 nm. Methods for forming the SOI layer are well known in the art. Non-limiting examples include SIMOX (Separation by Implantation of Oxygen), wafer bonding, and ELTRAN® (Epitaxial Layer TRANsfer). It may be understood by a person having ordinary skill in the art that the plurality of fins 104 may be etched from the SOI layer. Because the plurality of fins 104 may be etched from the SOI layer, they too may include any of the characteristics listed above for the SOI layer.

For clarity, when substrate 101 is a bulk substrate, the plurality of fins 104 may formed on the bulk substrate using known processes (e.g. etch fins, oxide fill, recess oxide, etc.).

The cap layer 106 may include any suitable insulating material such as, for example, silicon nitride. The cap layer 106 may be formed using known conventional deposition techniques, for example, low-pressure chemical vapor deposition (LPCVD). Cap layer 106 may be deposited upon the fin layer prior to fin formation as blanket layer. In one embodiment, the cap layer 106 may have a thickness ranging from about 5 nm to about 100 nm.

Referring now to FIG. 2, a cross section view of structure 100 is shown at an intermediate step during a process flow. At this step of fabrication, amorphous germanium (α-Ge) 120 is formed upon structure 100, according to various embodiments of the present invention, though polycrystalline Ge (poly-Ge), selective epitaxial Ge, may be also used. Generally, α-Ge 120 may be formed by process that grows, coats, or otherwise transfers α-Ge 120 onto semiconductor structure 100. For example, α-Ge 120 may be formed by applicable physical vapor deposition (PVD), CVD, electrochemical deposition (ECD), molecular beam epitaxy (MBE), or (ALD) techniques. At this stage of fabrication, α-Ge 120 is formed to a thickness to be coplanar with the top of the fins, or alternatively to be coplanar with the top of the upper surface of cap 106.

Polycrystalline or epitaxial Ge can be deposited by an epitaxial growth process that are, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition process for forming the germanium layer ranges from 300° C. to 600° C. A polycrystalline or epitaxial germanium layer can be deposited from a germanium gas source that is selected from the group consisting of germane, digermane, halogermane, dichlorogermane, trichlorogermane, tetrachlorogermane and combinations thereof.

Referring now to FIG. 3, a detailed cross section view of structure 100 is shown at an intermediate step during a process flow. At this step of fabrication, semiconductor structure 100 is annealed, according to various embodiments of the present invention. More specifically, at this stage of fabrication, known techniques are utilized to force Germanium to diffuse into the Si material of fins 104, thereby creating attenuated fins 140, accordingly to various embodiments of the present invention. Such known techniques may be heating semiconductor structure 100 to a exemplary temperature of 950° C., 960° C., etc., melting annealing, furnace annealing, rapid thermal annealing (RTA), Rapid Thermal Processing (RTP), non-melt anneal process completed in Epitaxy tool, etc. Utilizing such processes will typically change α-Ge 120 to polycrystalline germanium (poly-Ge) 130. Generally, other known techniques may be utilized to force the material surrounding fins 104 to diffuse into the material of fins 104.

Referring now to FIG. 4, a partial detailed cross section view of a attenuated fin 140 is shown, according to various embodiments of the present invention. Generally, attenuated fins 140 include an outer portion 150, inner portion 160, and an attenuated portion 170.

The outer portion 150 is the outermost portion of fin 140 and generally results from the forced diffusion of the material surrounding fins 104 into fins 104. Outer portion 150 is a compound material has the highest concentration of the material surrounding fins 104. For example, outer portion 150 may be 80% SiGe (i.e. SiGe with 80% Germanium concentration).

Inner portion 160 is the innermost portion of fin 150. Generally, inner portion 160 is the locations of fin 140 where the material surrounding fins 104 did not diffuse. As such, inner portion 160 generally includes only the original material of fins 104. Therefore, for example, inner portion 160 includes only Silicon.

Attenuated portion 170 generally includes an attenuated composite of a first material and a second material. The composite of the first material and second material generally results from the diffusion profile of the material surrounding fins 104 diffusing into fins 104. In certain embodiments, the attenuated composite is a graded, variable, or otherwise attenuated composite that is similar to the composition of outer portion 150 nearest outer portion 150 and attenuates to the composition of inner portion 160 nearest the inner portion 160. Therefore, for example, an attenuated portion 170 may be 100% Silicon nearest inner portion 160 and may be SiGe (80% Ge) nearest outer portion 150 with an attenuation from SiGe (e.g. 99.9% Si) near inner portion 160 to SiGe (e.g. 79.9% Ge) near outer portion 150 there between. In certain embodiments, attenuated portion 170 includes only the attenuated composition and not the compositions similar to outer portion 150 and inner portion 160. For clarity, it is noted that the outer SiGe concentration may be higher or lower than the exemplary 80% depending on diffusion conditions (e.g. anneal temperature, duration, etc.).

In certain embodiments, attenuated fin 140 generally includes a vertical outer channel along the perimeter formed by outer portion 150 and a vertical inner channel in the interior formed by inner portion 150. Therefore, the outer portion 150, inner portion 160, and attenuated portion 170 may have a substantially vertical orientation (i.e. height is greater than width).

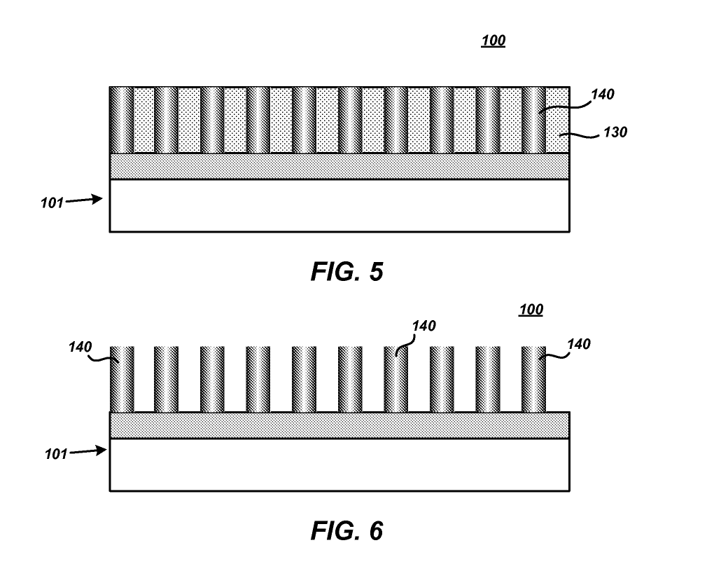

Referring now to FIG. 5, a cross section view of structure 100 is shown at an intermediate step during a process flow. At this step of fabrication, cap layer 106 is removed, according to various embodiments of the present invention. Generally, cap layer 106 may be removed by any known techniques. For example, cap layer 106 may be removed by an etch processes (wet etch, dry etch, etc.). Other such techniques may be utilized to remove cap layer 106 without departing from the scope of the embodiments herein claimed.

Referring now to FIG. 6, a cross section view of structure 100 is shown at an intermediate step during a process flow. At this step of fabrication, poly-Ge 130 is removed thereby exposing attenuated fins 140, according to various embodiments of the present invention. Generally, poly-Ge 130 may be removed by any known techniques. For example, poly-Ge 130 may be removed by an etch processes (wet etch, dry etch, etc.). In certain embodiments, poly-Ge 130 is etched selectively thereby leaving attenuated fins 140. Since attenuated fins have outer portion 150 comprising e.g. SiGe (80% Ge) there is an adequate percentage of non-Ge, that an etchant may selectively remove the surrounding poly-Ge 130 but leave attenuated fins 140. Other such techniques may be utilized to remove poly-Ge 130 without departing from the scope of the embodiments herein claimed. In certain embodiments, the cap layer 106 and poly-Ge 130 may be removed at the same stage of fabrication.

Though no further fabrication stages are depicted, it is to be understood that semiconductor structure 100 may undergo further fabrication processes to form a semiconductor device. For example, semiconductor structure 100 may undergo subsequent Front End of the Line stages, Middle of Line stages, and Back of the Line stages, etc.

Referring now to FIG. 7, a cross section view of structure 100 is shown at an intermediate step during a process flow. FIG. 7 depicts structure 100 at a similar stage of fabrication relative to FIG. 1. However, in the present alternate embodiment, structure 100 does not include cap layer 106. Therefore, for example, structure 100 may generally include the plurality of fins 104 etched upon substrate 101. As seen in further fabrication stages, the absence of cap layer 106 generally allows a multi dimensional diffusion profile of the material surrounding fins 104 diffusing into fins 104.

Referring now to FIG. 8, a cross section view of structure 100 is shown at an intermediate step during a process flow. At this step of fabrication, amorphous germanium (α-Ge) 120 is formed upon structure 100, according to various embodiments of the present invention, though polycrystalline Ge (poly-Ge), selective epitaxial Ge may alternatively be used. Generally, α-Ge 120 may be formed by process that grows, coats, or otherwise transfers α-Ge 120 onto semiconductor structure 100. For example, α-Ge 120 may be formed by applicable physical vapor deposition (PVD), CVD, electrochemical deposition (ECD), molecular beam epitaxy (MBE), or (ALD) techniques. At this stage of fabrication, α-Ge 120 is formed to a thickness greater than the height of fins 104.

Polycrystalline or epitaxial Ge can be deposited by an epitaxial growth process apparatuses that are, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition process for forming the germanium layer ranges from 300° C. to 600° C. A polycrystalline or epitaxial germanium layer can be deposited from a germanium gas source that is selected from the group consisting of germane, digermane, halogermane, dichlorogermane, trichlorogermane, tetrachlorogermane and combinations thereof.

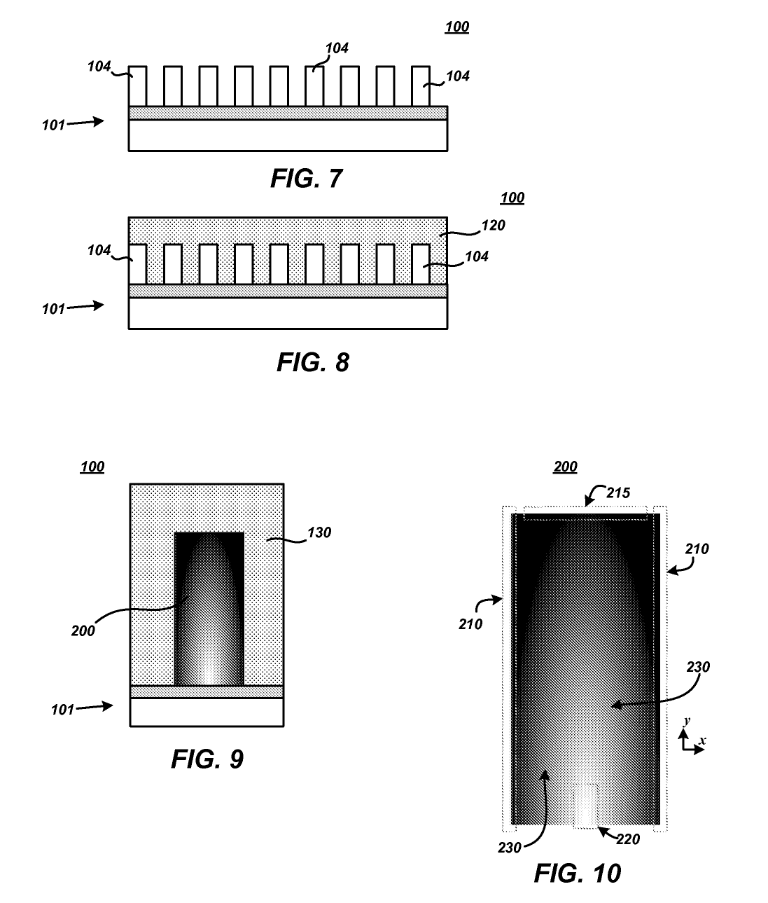

Referring now to FIG. 9, a detailed cross section view of structure 100 is shown at an intermediate step during a process flow. At this step of fabrication, semiconductor structure 100 may be annealed, according to various embodiments of the present invention. More generally, at this stage of fabrication, known techniques are utilized to force Germanium to diffuse into the Si material of fins 104 thereby creating multi dimensional attenuated fins 200 accordingly to various embodiments of the present invention. Such known techniques may be heating semiconductor structure 100 to a exemplary temperature of 950° C., 950° C., etc., melt annealing, furnace annealing, rapid thermal annealing (RTA), Rapid Thermal Processing (RTP), non-melt anneal process completed in Epitaxy tool, etc. Utilizing such processes will typically change α-Ge 120 to poly-Ge 130. Generally, other known techniques may be utilized to force the material surrounding fins 104 to diffuse into the material of fins 104 in order to create multi dimensional attenuated fins 200.

Referring now to FIG. 10, a partial detailed cross section view of a multi dimensional attenuated fin 200 is shown, according to various embodiments of the present invention. Generally, multi dimensional attenuated fin 200 include a vertical outer portion 210, horizontal outer portion 215, inner portion 220, and an attenuated portion 230.

The vertical outer portion 210 is the sidewall perimeter portion of fin 200 created by the aforementioned diffusion along the sidewall perimeter of fins 104. The horizontal outer portion 215 is the upper surface portion of fin 200 also created by the aforementioned diffusion along the top surface of fins 104. As such, outer portion 150 has the highest concentration of the material surrounding fins 104. Therefore, for example, vertical outer portion 210 and horizontal outer portion 215 may be 80% SiGe (i.e. SiGe with 80% Germanium concentration). The vertical outer portion 210 has a substantially vertical orientation (i.e. height is greater than width) and the horizontal outer portion 215 has a horizontal orientation (i.e. width is greater than height).

Inner portion 220 is the innermost portion of fin 200 and may be generally located at midpoint of the base of fin 200. Generally, inner portion 220 are the locations of fin 200 where the material surrounding fins 104 did not diffuse. As such, inner portion 220 generally includes only the original material of fins 104. Therefore, for example, inner portion 220 consists of only Silicon.

Attenuated portion 230 is formed from the multi dimensional diffusion profile of the material surrounding fins 104 diffusing into fins 104. In certain embodiments, the attenuated composite is a graded, variable, or otherwise attenuated material that is similar to the composition of vertical outer portion 210 and horizontal outer portion 215 nearest the vertical outer portion 210 and horizontal outer portion 215 and attenuates to the composition of inner portion 220 nearest the inner portion 220. Therefore, for example, an attenuated portion 230 may be 100% Silicon nearest vertical inner portion 220 and may be SiGe (80% Ge) nearest vertical outer portion 210 and nearest horizontal outer portion 215 and attenuates from SiGe (e.g. 99.9% Si) nearest inner portion 220 to SiGe (e.g. 79.9% Ge) nearest outer portions 210, 215 there between. In certain embodiments, attenuated portion 230 only includes the attenuated composition and not the compositions similar to vertical outer portion 210, horizontal outer portion 215, and inner portion 220. For clarity, it is noted that the outer SiGe concentration may be higher or lower than the exemplary 80% depending on diffusion conditions (e.g. anneal temperature, duration, etc.).

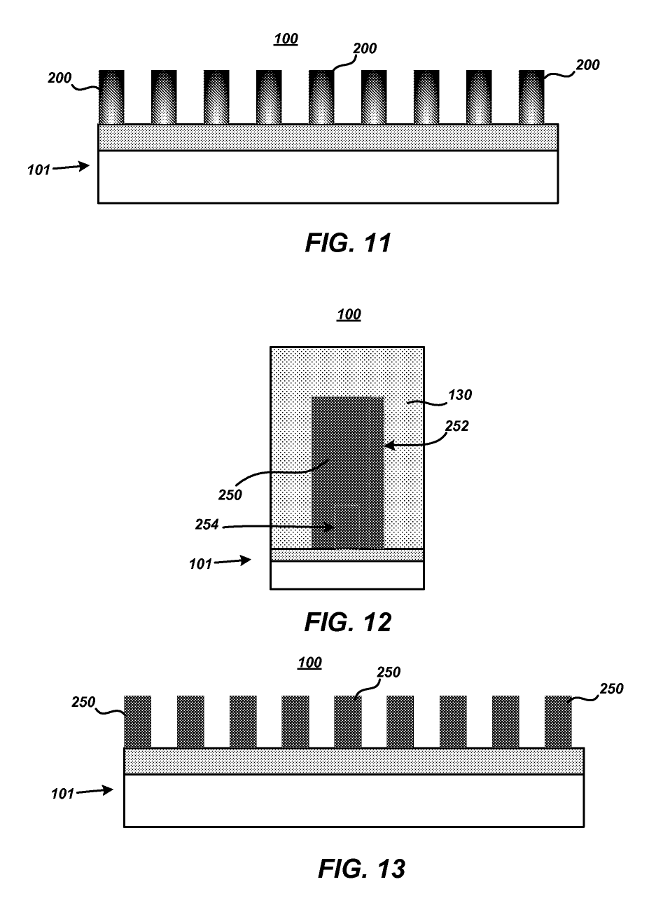

Referring now to FIG. 11, a cross section view of structure 100 is shown at an intermediate step during a process flow. At this step of fabrication, poly-Ge 130 is removed thereby exposing multi dimensional attenuated fins 200, according to various embodiments of the present invention. Generally, poly-Ge 130 may be removed by any known technique. For example, poly-Ge 130 may be removed by an etch processes (wet etch, dry etch, etc.). In certain embodiments, poly-Ge 130 is etched selectively thereby leaving multi dimensional attenuated fins 200. Since attenuated fins have vertical outer portion 210 and horizontal outer portion 215 comprising e.g. SiGe (80% Ge) there is an adequate percentage of non-Ge, that an etchant may selectively remove the surrounding poly-Ge 130 but leave multi dimensional attenuated fins 200. Other such techniques may be utilized to remove poly-Ge 130 without departing from the scope of the embodiments herein claimed. Though depicted as a final fabrication stage in FIG. 11, it is to be understood that semiconductor structure 100 may undergo further processes to form a semiconductor device.

Referring now to FIG. 12, a detailed cross section view of structure 100 is shown at an intermediate step during a process flow. At this step of fabrication, semiconductor structure 100 may be annealed, according to various embodiments of the present invention. More generally, at this stage of fabrication, known techniques are utilized to force Ge to fully diffuse into the Si material of fins 104 thereby creating composite fins 250 accordingly to various embodiments of the present invention. As such, FIG. 12 depicts an alternative embodiment to those embodiments shown in FIG. 3 and in FIG. 9 respectively. The known techniques may be heating semiconductor structure 100, furnace annealing, rapid thermal annealing (RTA), Rapid Thermal Processing (RTP), non-melt anneal process completed in Epitaxy tool, etc. Utilizing such processes will change α-Ge 120 to poly-Ge 130 and will create a fin 250 fully comprised of the composite of the material surrounding fins 104 and the material of fins 104. Composite fins 250 will typically not include a portion made up entirely of the original material of fins 104. In certain embodiments, composite fins 250 may include a first composite portion 252 that comprises the highest percentage of material previously surrounding fins 104. For example, portion 252 may comprise SiGe (80% Ge). In certain embodiments, composite fins 250 may include a second composite portion 254 that comprises the lowest percentage of material previously surrounding fins 104. For example, portion 254 may comprise SiGe (10% Ge). In certain embodiments, composite fins 250 may also include an attenuated portion that attenuates from a similar composition nearest portion 252 to a similar composition nearest portion 254.

Referring now to FIG. 13, a cross section view of structure 100 is shown at an intermediate step during a process flow. At this step of fabrication, poly-Ge 130 is removed, thereby exposing composite fins 250, according to various embodiments of the present invention. In certain embodiments, poly-Ge 130 is etched selectively thereby leaving attenuated fins 140. Since attenuated fins have outer portion 252 comprising e.g. SiGe (80% Ge) there is an adequate percentage of non-Ge, that an etchant may selectively remove the surrounding poly-Ge 130 but leave composite fins 250. Though depicted as a final fabrication stage in FIG. 13, it is to be understood that semiconductor structure 100 may undergo further processes to form a semiconductor device.

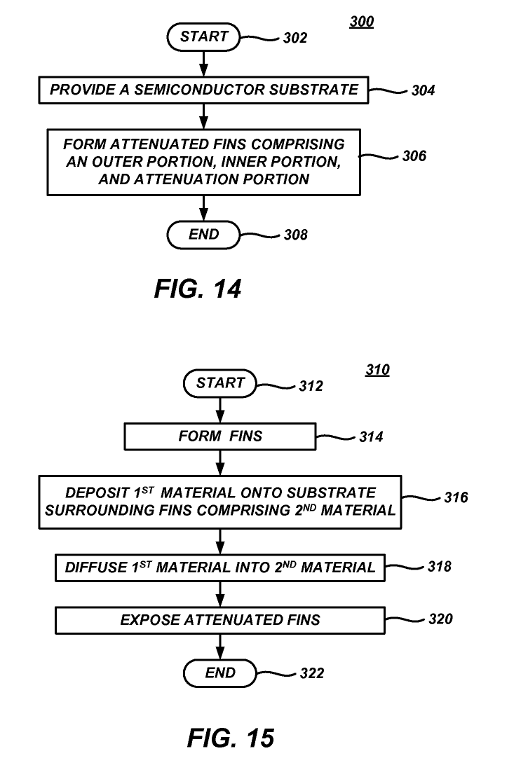

Referring now to FIG. 14, a process 300 of fabricating a semiconductor device is shown. Process 300 begins at block 302 and continues with providing semiconductor substrate 101 (block 304). For example, a semiconductor substrate 101 may be formed, received, manufactured, etc. Process 200 continues with forming attenuated fins (e.g. attenuated fins 140, multi dimensional attenuated fins 200, etc.) upon the semiconductor substrate 101 (block 306). In certain embodiments, the attenuated fins includes an outer portion and/or an upper portion including a composite of a first material and a second material, and inner portion may include only the second material, and an attenuation portion comprising an attenuated composite of the first material and the second material. In certain embodiments, the attenuated composite attenuates from a composite of the first material and the second material nearest the outer portion to a non-composite second material nearest the inner portion. Process 300 ends at block 308.

Referring now to FIG. 15, a process 310 of forming attenuated fins is shown. Process 310 begins at block 312 and continues with forming a cap 106 upon fins 104 comprising of the second material (block 314). Process 310 continues with depositing the first material 120 onto the substrate 101 surrounding a plurality of fins 104 (block 316). Process 310 continues with diffusing the first material 120 into the fins 104 comprising the second material (block 318). For example, the diffusing may be accomplished by annealing the substrate, the plurality of fins, and the first material. In certain embodiments the first material is Germanium (Ge) and the second material is Silicon (Si). Process 310 continues with exposing the attenuated fins (block 320). For example, the material surrounding the attenuated fins and the mask is etched or otherwise removed from the substrate. Process 310 ends at block 322.

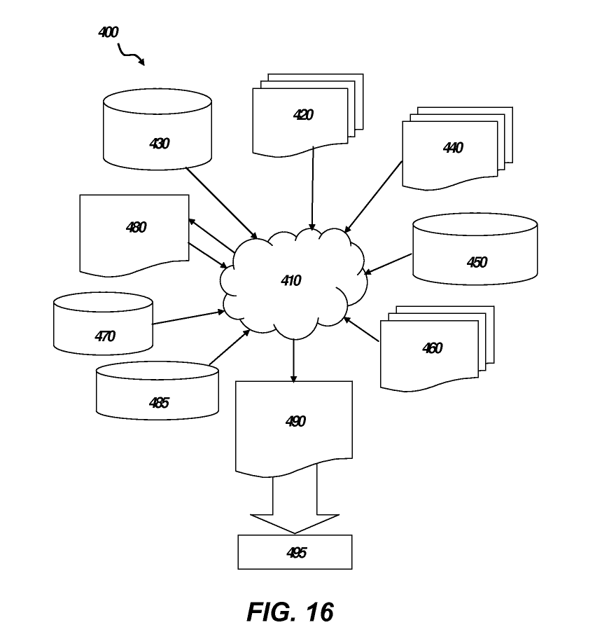

Referring now to FIG. 16, a block diagram of an exemplary design flow 400 used for example, in semiconductor integrated circuit (IC) logic design, simulation, test, layout, and/or manufacture is shown. Design flow 400 includes processes, machines and/or mechanisms for processing design structures or devices to generate logically or otherwise functionally equivalent representations of the structures and/or devices described above and shown in FIGS. 1-13.

The design structures processed and/or generated by design flow 400 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 400 may vary depending on the type of representation being designed. For example, a design flow 400 for building an application specific IC (ASIC) may differ from a design flow 400 for designing a standard component or from a design flow 400 for instantiating the design into a programmable array, for example a programmable gate array (PGA) or a field programmable gate array (FPGA) offered by Altera® Inc. or Xilinx® Inc.

FIG. 16 illustrates multiple such design structures including an input design structure 320 that is preferably processed by a design process 410. Design structure 420 may be a logical simulation design structure generated and processed by design process 410 to produce a logically equivalent functional representation of a hardware device. Design structure 420 may also or alternatively comprise data and/or program instructions that when processed by design process 410, generate a functional representation of the physical structure of a hardware device. Whether representing functional and/or structural design features, design structure 420 may be generated using electronic computer-aided design (ECAD) such as implemented by a core developer/designer.

When encoded on a machine-readable data transmission, gate array, or storage medium, design structure 420 may be accessed and processed by one or more hardware and/or software modules within design process 410 to simulate or otherwise functionally represent an electronic component, circuit, electronic or logic module, apparatus, device, structure, or system such as those shown in FIGS. 1-13. As such, design structure 420 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 410 preferably employs and incorporates hardware and/or software modules for synthesizing, translating, or otherwise processing a design/simulation functional equivalent of the components, circuits, devices, or structures shown FIGS. 1-13 to generate a Netlist 480 which may contain design structures such as design structure 420. Netlist 480 may comprise, for example, compiled or otherwise processed data structures representing a list of wires, discrete components, logic gates, control circuits, I/O devices, models, etc. that describes the connections to other elements and circuits in an integrated circuit design. Netlist 480 may be synthesized using an iterative process in which netlist 480 is resynthesized one or more times depending on design specifications and parameters for the device. As with other design structure types described herein, netlist 480 may be recorded on a machine-readable data storage medium or programmed into a programmable gate array. The storage medium may be a non-volatile storage medium such as a magnetic or optical disk drive, a programmable gate array, a compact flash, or other flash memory. Additionally, or in the alternative, the storage medium may be a system or cache memory, buffer space, or electrically or optically conductive devices in which data packets may be intermediately stored.

Design process 410 may include hardware and software modules for processing a variety of input data structure types including Netlist 480. Such data structure types may reside, for example, within library elements 430 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 440, characterization data 450, verification data 460, design rules 470, and test data files 485 which may include input test patterns, output test results, and other testing information. Design process 410 may further include, for example, standard mechanical design processes such as stress analysis, thermal analysis, mechanical event simulation, process simulation for operations such as casting, molding, and die press forming, etc.

One of ordinary skill in the art of mechanical design can appreciate the extent of possible mechanical design tools and applications used in design process 410 without deviating from the scope and spirit of the invention claimed herein. Design process 410 may also include modules for performing standard circuit design processes such as timing analysis, verification, design rule checking, place and route operations, etc.

Design process 410 employs and incorporates logic and physical design tools such as HDL compilers and simulation model build tools to process design structure 420 together with some or all of the depicted supporting data structures along with any additional mechanical design or data (if applicable), to generate a second design structure 490. Design structure 490 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures).

Similar to design structure 420, design structure 490 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-13. In one embodiment, design structure 490 may comprise a compiled, executable HDL simulation model that functionally simulates the devices shown in FIGS. 1-13.

Design structure 490 may also employ a data format used for the exchange of layout data of integrated circuits and/or symbolic data format (e.g. information stored in a GDSII (GDS2), GL1, OASIS, map files, or any other suitable format for storing such design data structures). Design structure 490 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-13. Design structure 490 may then proceed to a stage 495 where, for example, design structure 490: proceeds to tape-out, is released to manufacturing, is released to a mask house, is sent to another design house, is sent back to the customer, etc.

The accompanying figures and this description depicted and described embodiments of the present invention, and features and components thereof. Those skilled in the art will appreciate that any particular nomenclature used in this description was merely for convenience, and thus the invention should not be limited by the specific process identified and/or implied by such nomenclature. Therefore, it is desired that the embodiments described herein be considered in all respects as illustrative, not restrictive, and that reference be made to the appended claims for determining the scope of the invention.

References herein to terms such as “vertical”, “horizontal”, etc. are made by way of example, and not by way of limitation, to establish a frame of reference. The term “horizontal” as used herein is defined as a plane parallel to the conventional plane or surface of the substrate, regardless of the actual spatial orientation of the semiconductor substrate. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The invention claimed is:

1. A method of fabricating a semiconductor device, the method comprising:
providing a semiconductor substrate, and;
forming attenuated fins upon the substrate, a particular attenuated fin comprising:
an outer portion comprising a composite of a first material and a second material;
an inner portion comprising the second material, and;
an attenuation portion comprising an attenuated composite of the first material and the second material.

2. The method of claim 1 wherein forming attenuated fins upon the substrate further comprises:
depositing the first material onto the substrate surrounding a plurality of fins that comprise the second material, and;
diffusing the first material into the plurality of fins.

3. The method of claim 1 wherein the first material is Germanium (Ge), the second material is Silicon (Si), and the attenuated composite is attenuated SiGe.

4. The method of claim 1 wherein the outer portion further comprising:
an upper portion comprising the first material.

5. The method of claim 2 wherein the plurality of fins comprise a cap thereupon.

6. The method of claim 1 wherein the attenuated composite varies from a first composite to a second composite, the first composite comprising a majority of the first material, the second composite comprising a majority of the second material.

7. The method of claim 2 wherein forming attenuated fins upon the substrate further comprises:
subsequent to diffusing, exposing the attenuated fins by removing the material surrounding the attenuated fins from substrate.

8. A semiconductor device comprising:
a silicon substrate, and;
a plurality of attenuated fins upon the substrate, the attenuated fins comprising:
an attenuated portion comprising an attenuated composite of a first material and a second material.

9. The semiconductor device of claim 8 wherein the attenuated fins further comprise:
an outer portion comprising a composite of the first material and the second material.

10. The semiconductor device of claim 8 wherein the attenuated fins further comprise:
an inner portion comprising the second material.

11. The semiconductor device of claim 8 wherein the attenuated fins further comprise:
an upper portion comprising the first material.

12. The semiconductor device of claim 8 wherein the attenuated composite varies from a first composite to a second composite, the first composite comprising a majority of the first material, the second composite comprising a majority of the second material.

13. The semiconductor device of claim 8 wherein the first material is Germanium (Ge) and the second material is Silicon (Si).

14. The semiconductor device of claim 11 wherein the outer portion and the inner portion have a substantially vertical orientation and the upper portion has a substantially horizontal orientation.

15. A design structure embodied in a machine readable storage medium for designing, manufacturing, or testing an integrated circuit, the design structure comprising:
a silicon substrate, and;
a plurality of attenuated fins upon the substrate, the attenuated fins comprising:
an attenuated portion comprising an attenuated composite of a first material and a second material.

16. The design structure of claim 15 wherein the attenuated fins further comprise:
an outer portion comprising a composite of the first material and the second material.

17. The design structure of claim 15 wherein the attenuated fins further comprise:
an inner portion comprising the second material.

18. The design structure of claim 15 wherein the attenuated fins further comprise:
an upper portion comprising the first material.

19. The design structure of claim 15 wherein the attenuated composite varies from a first composite to a second composite, the first composite comprising a majority of the first material, the second composite comprising a majority of the second material.

20. The design structure of claim 15 wherein the first material is Germanium (Ge) and the second material is Silicon (Si).
